(19) United States
(12) Patent Application Publication
(10) Pub. No.: US 2012/0222719 A1
(43) Pub. Date: Sep. 6, 2012

(54) SOLAR BATTERY MODULE AND METHOD FOR MANUFACTURING THE SAME

(75) Inventors: Keiichiro Utsunomiya, Tokyo (JP); Tatsuya Ishigaki, Tokyo (JP)

(73) Assignee: Mitsubishi Electric Corporation, Chiyoda-ku (JP)

(21) Appl. No.: 13/508,705

(22) PCT Filed: Nov. 9, 2009
(86) PCT No.: PCT/JP2009/069056

§ 371 Date: May 8, 2012

(51) Int. Cl. H01L 31/05; H01L 31/18

(52) U.S. Cl. 136/244; 438/80; 257/E31.114

(57) ABSTRACT

A solar battery module includes a first cell line formed by arraying a plurality of solar battery cells in a first direction, a first inter-cell lead that connects the solar battery cells in the first cell line in an array direction, a second cell line formed by arraying the solar battery cells in parallel to the first cell line, a second inter-cell lead that connects the solar battery cells forming the second cell line in an array direction, and an inter-line lead that extends in a direction perpendicular to the first direction and electrically connects the first inter-cell lead and the second inter-cell lead, in which at least a portion of the inter-line lead overlaps the solar battery cell.

### FIELD

The present invention relates to a solar battery module in which a plurality of solar battery cells that are respectively formed in flat plates and have light-receiving-surface electrodes on a light-receiving surface side and back-surface electrodes on a back surface side are arranged longitudinally and transversely, and the light-receiving-surface electrodes and the back-surface electrodes of adjacent ones of the solar battery cells are connected sequentially with leads, and also relates to a method for manufacturing the same.

### BACKGROUND

Solar power generation converts solar light directly into electric power. Because the solar power generation is ecologically friendly and produces unlimited supplies of electricity, it has been drawing public attention recently as a new energy source. Due to a lower amount of electric power output per solar battery cell, a plurality of solar battery cells are generally connected in series to extract a practical amount of electric power output.

A stacked body that constitutes a solar battery module is formed by stacking, from its light-receiving surface side, a translucent substrate made of a transparent material such as glass, a light-receiving-surface-side sealing member (first resin layer) made of transparent resin, a solar battery array in which a plurality of solar battery cells are arrayed in a lattice pattern and leads that connect the solar battery cells in series are arranged, a back-surface-side sealing member (second resin layer) made of transparent resin, and a weather-resistant back sheet in this order.

Each of the solar battery cells made of polycrystalline silicon has a thickness of about 0.16 to 0.3 millimeter. A clearance of 2 to 4 millimeters is created between adjacent ones of the solar battery cells. A clearance of 2 to 4 millimeters is created between lines of the arrayed solar battery cells.

As the leads that electrically connect the solar battery cells, a solder-plated rectangular copper wire is used. A resistance of the leads needs to decrease to reduce their resistance loss to improve performance of the solar battery module. Therefore, for example, an increase of a cross-sectional area of the leads has been examined.

However, when the leads have a larger width to increase a cross-sectional area of the leads, the solar battery module has larger outer dimensions. This causes a cost increase of the translucent substrate, the sealing members, the back sheet and the like, and also leads to a reduction in the power generation efficiency of the solar battery module. When the leads have a larger thickness, the sealing members as insulating layers have a smaller thickness, which causes a reduction in insulating performance. If the sealing members or the back sheet has a larger thickness to secure a predetermined amount of thickness of the insulating layers, this causes a cost increase.

Conventionally, a lead that connects two lines of solar battery cell groups (cell lines) to each other is arranged to protrude to a non-power generation field around the solar battery array. Because the non-power generation field does not contribute to power generation, an area of this field can be eliminated to improve the power generation efficiency of the solar battery module.

Meanwhile, the solar battery module constituted as mentioned above generally has paired positive and negative extraction wires connected to the solar battery array to extract electric power from the solar battery array. In such a solar battery module, one terminal box is located on the back surface of the solar battery module, and the paired positive and negative extraction wires are placed to extend along the outer periphery (the non-power generation field) of the solar battery array from positions where the extraction wires are connected to the ends of the solar battery array to positions which allow the extraction wires to be easily drawn out to the terminal box, respectively.

Conventionally, a proposal has been made for such a solar battery module that the extraction wires, which extend from the solar battery array to the terminal box, are provided to overlap the back surface of the solar battery cells. This prevents the extraction wires from being placed in the non-power generation field around the solar battery array, which decreases an area of the non-power generation field, and thus improves the power generation efficiency (see, for example, Patent Literature 1).

### CITATION LIST

### Patent Literature

Patent Literature 1: Japanese Patent Application Laid-open No. 2008-300449

### SUMMARY

### Technical Problem

However, in the solar battery module proposed in Patent Literature 1, the extraction wires are drawn along the outer periphery of the solar battery array only in a extremely small part of the non-power generation field, while the leads that electrically connect the adjacent solar battery cell groups (cell lines) to each other remain placed in this non-power generation field. These leads that connect between the cell lines prevent a substantial decrease in the area of the non-power generation field around the solar battery cells. This causes a problem that any substantial improvement in the power generation efficiency cannot be expected.

The present invention has been achieved to solve the above problems, and an object of the present invention is to provide a solar battery module that can reduce a non-power generation field extending in an outer peripheral portion of a solar battery array, thereby decreasing outer dimensions and improving the power generation efficiency, and a method for manufacturing the same.

### Solution to Problem

There is provided a solar battery module according to an aspect of the present invention in which a plurality of solar battery cells that are respectively formed in flat plates and have light-receiving-surface electrodes on a light-receiving surface side and back-surface electrodes on a back surface side are arranged longitudinally and transversely, and the light-receiving-surface electrodes and the back-surface electrodes of adjacent ones of the solar battery cells are connected sequentially with leads, the module including: a first cell line formed by arraying the solar battery cells in a first direction; a first inter-cell lead that connects the solar battery cells that form the first cell line in an array direction; a second cell line formed by arraying the solar battery cells in parallel to the first cell line; a second inter-cell lead that connects the solar battery cells that form the second cell line in an array direction; and an inter-line lead that extends in a direction perpendicular to the first direction and electrically connects the first inter-cell lead and the second inter-cell lead, wherein the inter-line lead overlaps at least either one of the solar battery cell in the first cell line and the solar battery cell in the second cell line.

Furthermore, there is provided a method for manufacturing a solar battery module according to another aspect of the present invention in which a plurality of solar battery cells that are respectively formed in flat plates and have light-receiving-surface electrodes on a light-receiving surface side and back-surface electrodes on a back surface side are arranged longitudinally and transversely, and the light-receiving-surface electrodes and the back-surface electrodes of adjacent ones of the solar battery cells are connected sequentially with leads, the method including: arraying the solar battery cells in a first direction to form a first cell line; arraying the solar battery cells in parallel to the first cell line to form a second cell line; connecting the solar battery cells that form the first cell line with a first inter-cell lead in an array direction; connecting the solar battery cells that form the second cell line with a second inter-cell lead in an array direction; and connecting the first inter-cell lead and the second inter-cell lead with an inter-line lead that extends in a direction perpendicular to the first direction and overlaps the solar battery cell in at least either one of the solar battery cell in the first cell line and the solar battery cell in the second cell line.

### Advantageous Effects of Invention

According to the solar battery module of the present invention, the inter-line lead, conventionally placed along an outer peripheral portion of the cell lines, is provided to overlap the solar battery cell. This can reduce the non-power generation field extending in an outer peripheral portion of the solar battery array, thereby decreasing the outer dimensions of the solar battery module and improving the power generation efficiency of the solar battery module.

Furthermore, according to the method for manufacturing a solar battery module of the present invention, the first inter-cell lead and the second inter-cell lead are connected with the inter-line lead that overlaps the solar battery cell in at least either one of the first cell line and the second cell line. This can reduce the non-power generation field extending in an outer peripheral portion of the solar battery array, and allows manufacturing of a solar battery module with smaller outer dimensions and higher power generation efficiency.

### BRIEF DESCRIPTION OF DRAWINGS

FIG. 1 is a perspective view of relevant parts of a solar battery module according to a first embodiment of the present invention, as viewed from its back surface side.

FIG. 2 is an exploded perspective view of the relevant parts of the solar battery module in FIG. 1.

FIG. 3 is an enlarged backside view of a solar battery array in FIG. 2, as enlargedly viewed from its back surface side.

FIG. 4 is a perspective view of relevant parts of a conventional solar battery module for comparison, as viewed from its back surface side.

FIG. 5 is an enlarged backside view of a solar battery array in FIG. 4, as enlargedly viewed from its back surface side.

FIG. 6 is an enlarged backside view of a solar battery array of a solar battery module according to a second embodiment of the present invention, as enlargedly viewed from its back surface side.

FIG. 7 is an enlarged backside view of a solar battery array of a solar battery module according to a third embodiment of the present invention, as enlargedly viewed from its back surface side.

### DESCRIPTION OF EMBODIMENTS

Exemplary embodiments of a solar battery module and a method for manufacturing the same according to the present invention will be explained below in detail with reference to the accompanying drawings. The present invention is not limited to the embodiments.

### First Embodiment

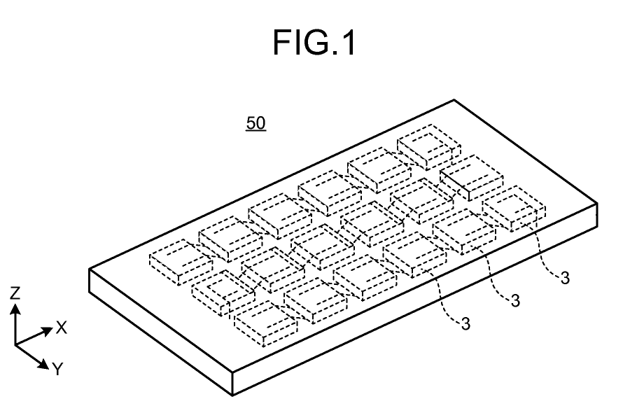

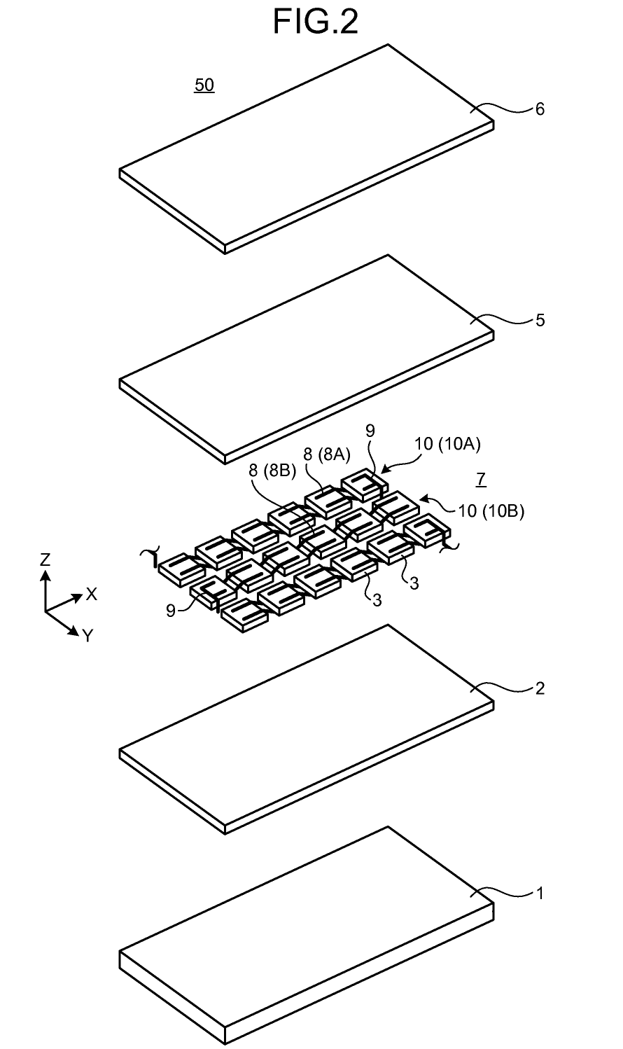

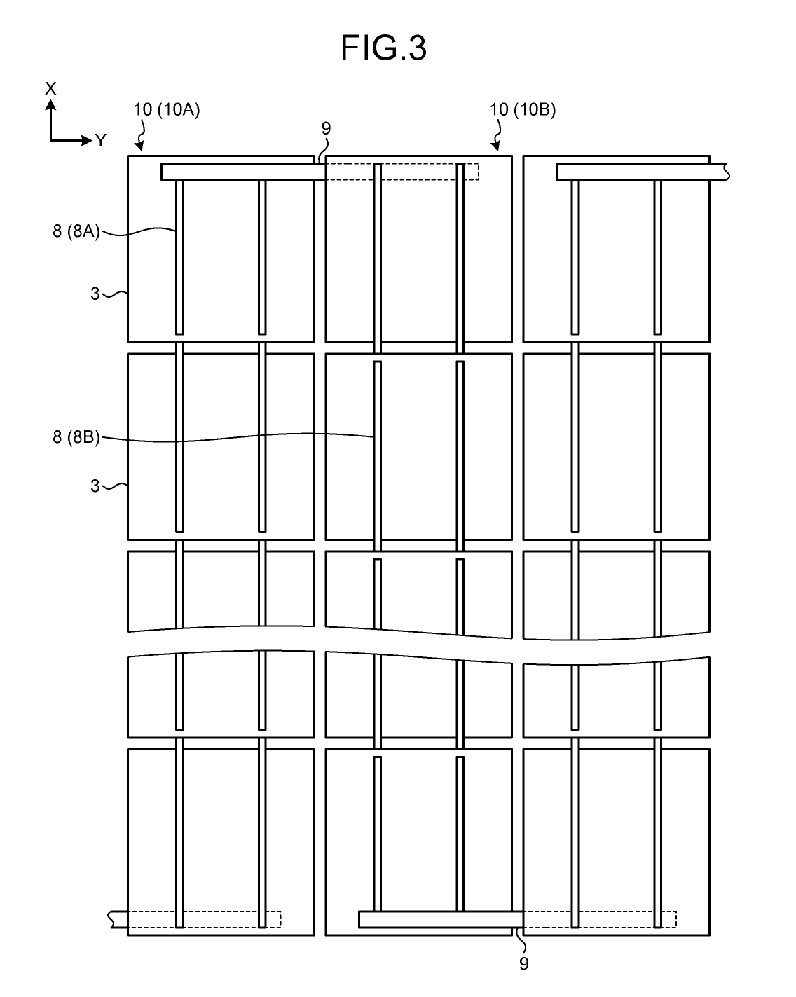

FIG. 1 is a perspective view of relevant parts (stacked body) of a solar battery module according a first embodiment of the present invention, as viewed from its back surface side. FIG. 2 is an exploded perspective view of the relevant parts of the solar battery module in FIG. 1. FIG. 3 is an enlarged backside view of a solar battery array in FIG. 2, as enlargedly viewed from its back surface side.

In FIGS. 1 to 3, a stacked body that constitutes relevant parts of a solar battery module 50 is formed by stacking, from its light-receiving surface side, a translucent substrate 1 made of a transparent material such as glass, a light-receiving-surface-side sealing member (first resin layer) 2 made of transparent resin, a solar battery array 7 in which a plurality of solar battery cells 3 are arranged in a lattice pattern and leads 8 and 9 that connect the solar battery cells 3 in series are arranged, a back-surface-side sealing member (second resin layer) 5 made of transparent resin, and a weather-resistant back sheet 6 in this order. The light-receiving-surface-side sealing member 2 and the back-surface-side sealing member 5 are integrated into one unit by heat treatment to seal the solar battery array 7 with resin to form a resin-sealed layer. The stacked body thus constituted is entirely covered along its outer peripheral edges by a frame (not shown), so that the solar battery module 50 is manufactured.

The solar battery cells 3 are made from a monocrystalline or polycrystalline silicon substrate, or the like with a thickness of about 0.16 to 0.3 millimeter, and arrayed in a lattice pattern. In the solar battery cells 3, a P-N junction is formed in its interior, electrodes are provided respectively on its light-receiving surface and back surface, and an antireflective coating is provided on its light-receiving surface. In the case of a polycrystalline silicon solar battery, the solar battery cell 3 is sized to have a side length of about 150 to 156 millimeters. The solar battery cells 3 has a light-receiving-surface electrode (positive) on the light-receiving surface side and a back-surface electrode (negative) on the back surface side.

In the solar battery array 7, a plurality of cell lines 10 each formed by arraying the solar battery cells 3 in a first direction (an X direction) are provided in parallel in a direction (a Y direction) perpendicular to the first direction. In this explanation, two predetermined adjacent cell lines of the cell lines 10 arranged in the first direction are referred to as a first cell line 10A and a second cell line 10B, respectively. However, other cell lines 10 are also constituted in the same manner.

The solar battery cells 3 are connected with leads. The leads include a plurality of inter-cell leads 8 that connect between the solar battery cells 3 in series, and a plurality of inter-line leads 9 that connect the cell lines (solar battery cell groups) 10, connected together with the inter-cell leads 8, to each other in series. In this example, some of the inter-cell leads 8, which connect the solar battery cells 3 that form the first cell line 10A, are specifically referred to as first inter-cell leads 8A. In addition, some of the inter-cell leads 8, which connect the solar battery cells 3 that form the second cell line 10B, are specifically referred to as second inter-cell leads 8B. However, the other inter-cell leads 8 are also constituted in the same manner.

The first inter-cell leads 8A, the second inter-cell leads 8B, and the inter-line leads 9 are made of a solder-plated rectangular copper wire with a thickness of about 0.1 to 0.4 millimeter. The first inter-cell leads 8A and the second inter-cell leads 8B are joined by soldering to the solar battery cells 3 to electrically connect the back-surface electrodes (negative) and the light-receiving-surface electrodes (positive) of the solar battery cells 3. The inter-cell leads 8A and 8B sequentially connect the back-surface-side electrodes and the light-receiving-surface-side electrodes of the solar battery cells 3, arranged in a lattice pattern, in a longitudinal direction of the solar battery module 50. In adjacent cell lines 10, the back-surface-side electrodes and the light-receiving-surface-side electrodes are connected in opposite directions. At the end of the cell lines 10, the inter-line lead 9 connects the solar battery cells 3, located at the respective ends of the adjacent cell lines 10, to each other in a turning manner. This allows the solar battery cells 3 arranged in a lattice pattern to be entirely connected in series. Although the inter-cell lead 8 according to the present embodiment is a single continuous line, the inter-cell lead 8 can be two separate lines provided respectively on the light-receiving surface side and the back surface side of the solar battery cells 3 and connected together.

Further details of the present embodiment are described below. As described above, the solar battery cells 3 that form the first cell line 10A are connected in series with the first inter-cell leads 8A. Each of the first inter-cell leads 8A is provided between adjacent ones of the solar battery cells 3 arranged in one line. The first inter-cell leads 8A respectively connect the light-receiving-surface electrodes (positive) and the back-surface electrodes (negative) of the solar battery cells 3 in such a manner that the first cell line has a predetermined polarity. That is, in FIG. 2, the first inter-cell leads 8A connect the back-surface electrode of a predetermined one of the solar battery cells 3 and the light-receiving-surface electrode of the solar battery cell 3 rightward adjacent to the predetermined one.

Meanwhile, the solar battery cells 3 that form the second cell line 10B are connected in series with the second inter-cell leads 8B. Each of the second inter-cell leads 8B is provided between adjacent ones of the solar battery cells 3 arranged in one line. The second inter-cell leads 8B respectively connect the light-receiving-surface electrodes and the back-surface electrodes of the solar battery cells 3 in such a manner that the second cell line has an opposite polarity to the first cell line 10A. That is, in FIG. 2, the second inter-cell leads 8B connect the back-surface electrode of a predetermined one of the solar battery cells 3 and the light-receiving-surface electrode of the solar battery cell 3 leftward adjacent to the predetermined one.

The first cell line 10A and the second cell line 10B connected as described above are connected with the inter-line lead 9 at their right ends in FIG. 2. That is, the back-surface electrode of the solar battery cell 3 located at the right end of the first cell line 10A and the light-receiving-surface electrode of the solar battery cell 3 located at the right end of the second cell line 10B are connected with the inter-line lead 9. This allows all the solar battery cells 3 to be connected in series. As a feature of the present embodiment, the inter-line lead 9 is provided to overlap the solar battery cells 3 located at the respective right ends of the first cell line 10A and the second cell line 10B in FIG. 2.

Materials and the like of the other members are mentioned below. A glass material or a synthetic resin material such as polycarbonate resin is used for the translucent substrate 1. As the glass material, white plate glass, tempered glass, heat reflective glass, or the like is used, and a white tempered glass plate with a thickness of about 3 to 4 millimeters is commonly used. As the polycarbonate resin material, one with a thickness of about 5 millimeters is commonly used.

A material with translucent, heat-resisting, electrical-insulating, and flexible properties is used for the light-receiving-surface-side sealing member 2, and preferably a thermoplastic synthetic resin material that contains ethylene vinyl acetate (EVA), polyvinyl butyral (PVB), or the like as a main ingredient is used. Such a material in a sheet form with a thickness of about 0.6 to 1.0 millimeter is used.

Similarly to the light-receiving-surface-side sealing member 2, a material with translucent, heat-resisting, electrical-insulating, and flexible properties is used for the back-surface-side sealing member 5, and preferably a thermoplastic synthetic resin material that contains ethylene vinyl acetate (EVA), polyvinyl butyral (PVB), or the like as a main ingredient is used. Such a material in a sheet form with a thickness of about 0.4 to 1.0 millimeter is used.

The light-receiving-surface-side sealing member 2 and the back-surface-side sealing member 5 are thermally cross-linked by heating at a laminating process under a reduced atmospheric pressure of about 0.5 to 1.0 atm to be fused to the translucent substrate 1, the solar battery array 7, and the back sheet 6, thereby integrating them into one unit.

A material with high permeable, weather-resistant, hydrolysis-resistant, and insulating properties, such as a fluorine resin sheet and a polyethylene terephthalate (PET) sheet coated with evaporated alumina or silica, is used for the back sheet 6.

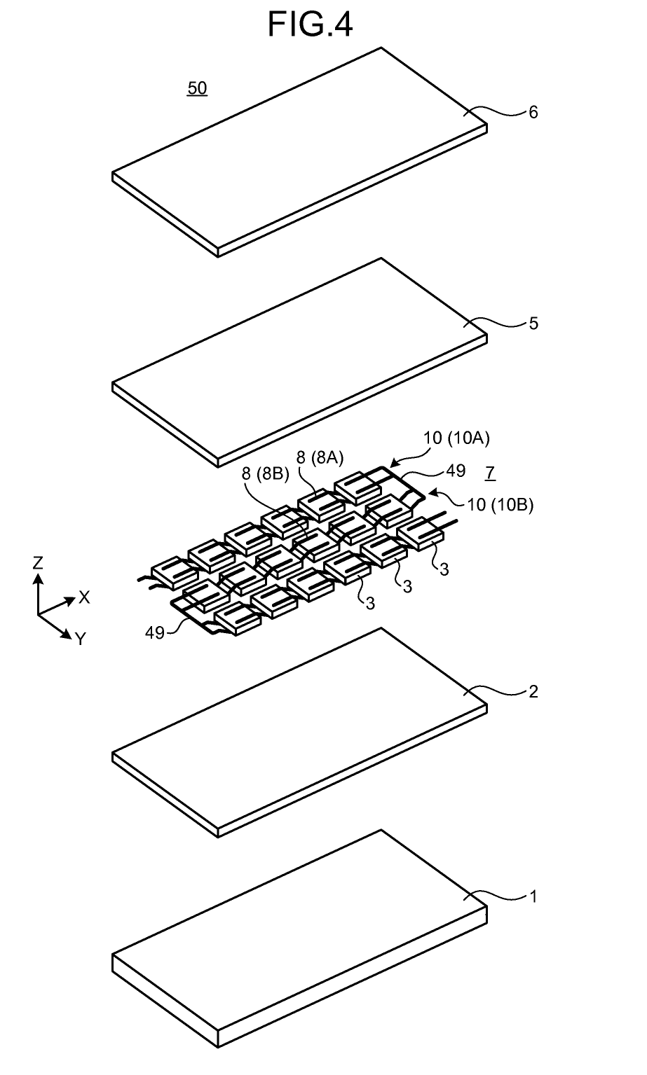

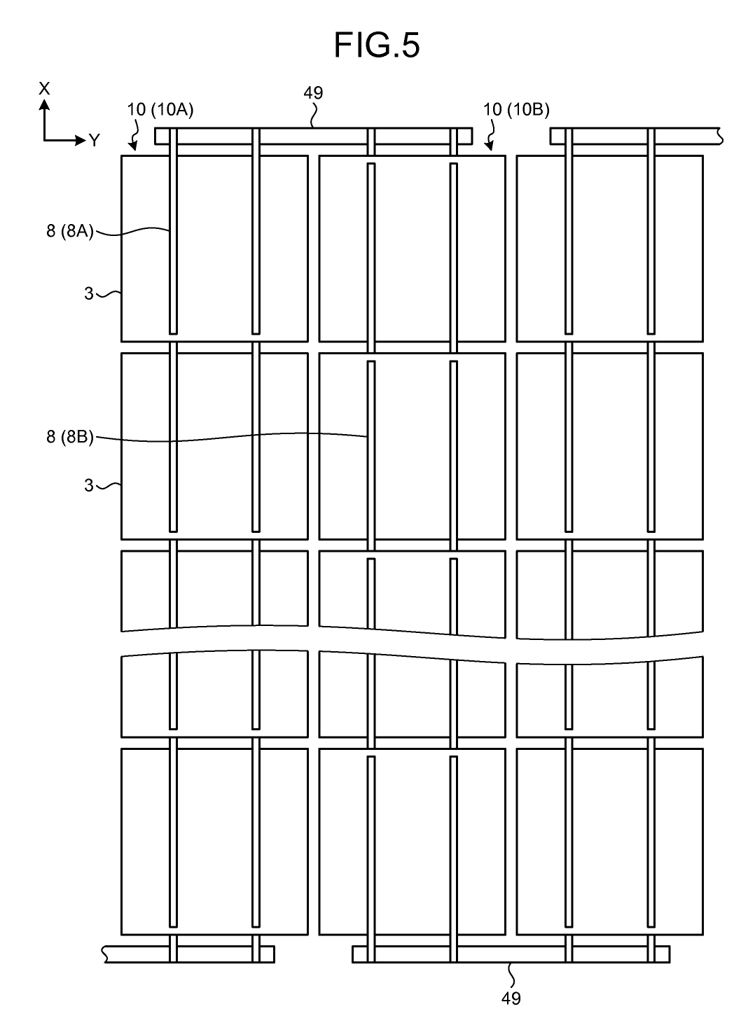

FIG. 4 is a perspective view of relevant parts of a conventional solar battery module, as viewed from its back surface side, for comparison. FIG. 5 is an enlarged backside view of a solar battery array in FIG. 4, as enlargedly viewed from its back surface side. A conventional inter-line lead 49 connects the first inter-cell leads 8A and the second inter-cell leads 8B at a position (a non-power generation field) protruding from the solar battery cells 3 located at the respective ends of the cell lines 10. The inter-cell leads 8A and 8B and the inter-line leads 49 protrude from the solar battery cells 3, and accordingly the conventional solar battery module has larger outer dimensions than those in the present embodiment.

According to the solar battery module 50 of the present embodiment, the inter-line lead 9 is located at a position where it overlaps the solar battery cells 3 to extend from the back surface side to the light-receiving surface side of the solar battery cells 3. This eliminates the area occupied by the inter-line leads 9, and thus reduces module outer dimensions, thereby reducing the cost of the members and improving the module power generation efficiency.

In addition, some of the first inter-cell leads 8A and the second inter-cell leads 8B, which connect the solar battery cells 3 and the inter-line lead 9, are also reduced in length. Accordingly, the resistance loss is reduced, thereby increasing a module power generation amount.

### Second Embodiment

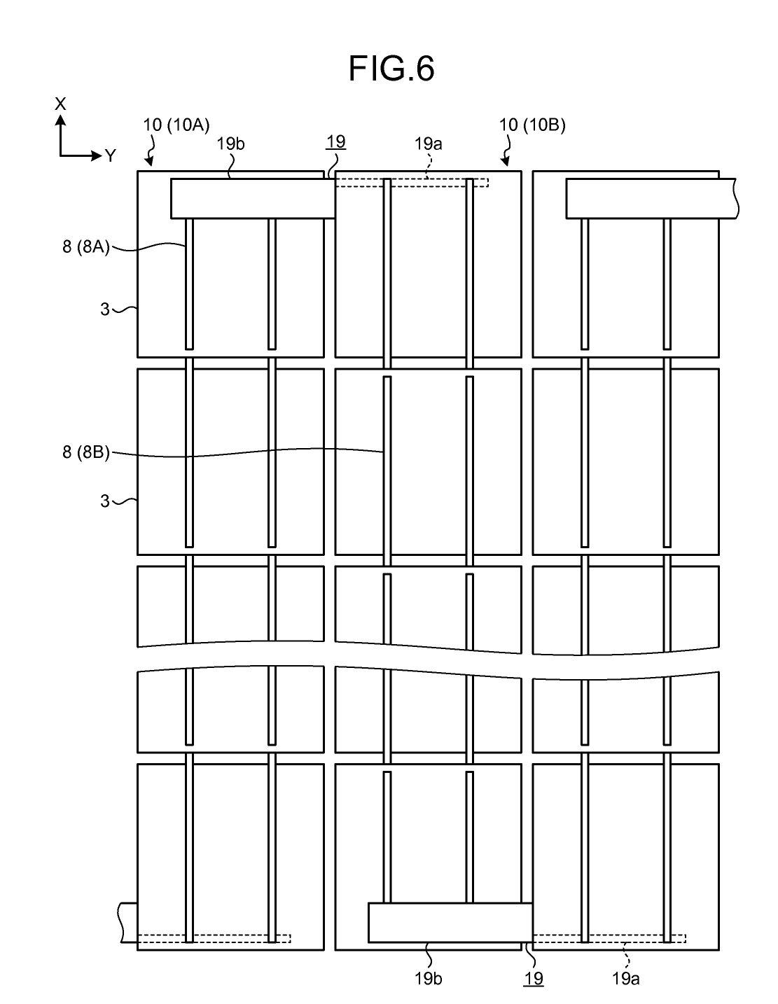

FIG. 6 is an enlarged backside view of a solar battery array of a solar battery module according to a second embodiment of the present invention, as enlargedly viewed from its back surface side. In an inter-line lead 19 according to the present embodiment, a light-receiving-surface-side overlapping portion 19a that extends on the light-receiving surface side of the solar battery cell 3 in the second cell line 10B and overlaps the solar battery cell 3 has a smaller width compared to the inter-line lead 9 according to the first embodiment. In contrast, in the inter-line lead 19, a back-surface-side overlapping portion 19b that extends on the back surface side of the solar battery cell 3 in the first cell line 10A and overlaps the solar battery cell 3 has a larger width. Other configuration is the same as that in the first embodiment.

As described above, a portion of the inter-line lead 19, which is positioned on the back surface of the solar battery cell 3, has a larger width. This reduces a lead resistance without causing an increase in the module outer dimensions. Thus, the resistance loss is reduced, thereby increasing the power generation amount of the solar battery module and improving the power generation efficiency of the solar battery module.

Meanwhile, a portion of the inter-line lead 19, which is positioned on the front surface of the solar battery cell 3, has a smaller width. This suppresses a reduction in the module power generation amount due to the decreased light-receiving area of the solar battery cells 3.

### Third Embodiment

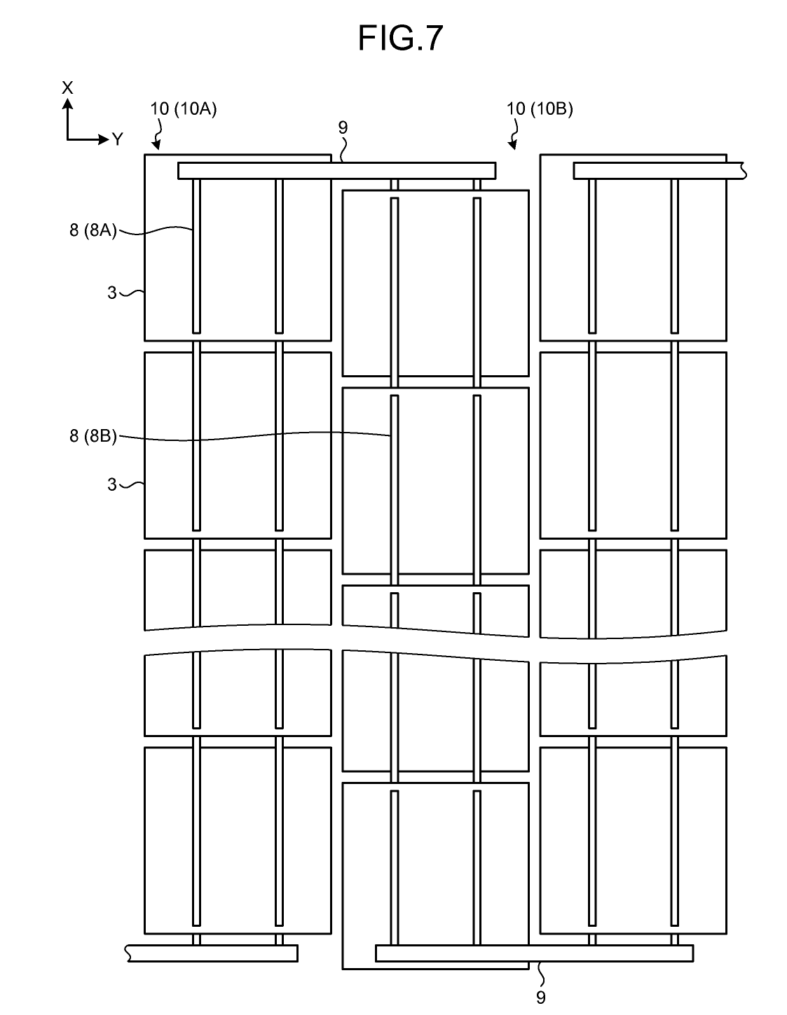

FIG. 7 is an enlarged backside view of a solar battery array of a solar battery module according to a third embodiment of the present invention, as enlargedly viewed from its back surface side. According to the present embodiment, the second cell line 10B is displaced in the first direction in such a manner that its end on the side where the inter-line lead 9 is provided is at a position retracted toward the module center relative to the end of the first cell line 10A. The inter-line lead 9 is provided to overlap the solar battery cell 3 on its back surface side at the end of the first cell line 10A and not to overlap the solar battery cell 3 at the end of the second cell line 10B. That is, the inter-line lead 9 according to the present embodiment overlaps the solar battery cell 3 on its back surface side, and does not overlap the solar battery cell 3 on its light-receiving surface side. Except this arrangement, the solar battery array is constituted in the same manner as the first embodiment. Although FIG. 7 shows only a part of the solar battery array and the whole part cannot thus be confirmed, the cell lines 10 including those not shown in FIG. 7 are entirely arranged to be alternately displaced in the first direction in such a manner that their ends are protruded and retracted.

As described above, according to the solar battery module of the present embodiment, the cell lines 10 are arranged to be displaced in the first direction in such a manner that a portion of the inter-line lead 9, which extends on the back surface side of the solar battery cell 3 in either one of the cell lines 10, overlaps the solar battery cell 3, and the other portion does not overlap the solar battery cell 3 in the other cell line 10. This results in a reduction in the outer dimensions of the solar battery module, while maintaining the light-receiving area of the solar battery cells 3, although the reduction in the module outer dimensions is not as significant as in the first embodiment. Therefore, the power generation efficiency of the solar battery module can be improved.

### INDUSTRIAL APPLICABILITY

As described above, the solar battery module according to the present invention is useful for a solar cell module to be installed on a place such as a roof of a building, and is particularly suitable for a solar battery module in which a plurality of solar battery cells respectively having light-receiving-surface electrodes and back-surface electrodes are arranged longitudinally and transversely, and the light-receiving-surface electrodes and the back-surface electrodes of adjacent ones of the solar battery cells are connected sequentially with leads.

### REFERENCE SIGNS LIST

1 TRANSLUCENT SUBSTRATE
2 LIGHT-RECEIVING-SURFACE-SIDE SEALING MEMBER
3 SOLAR BATTERY CELL
5 BACK-SURFACE-SIDE SEALING MEMBER
6 BACK SHEET
7 SOLAR BATTERY ARRAY
8 INTER-CELL LEAD
8A FIRST INTER-CELL LEAD
8B SECOND INTER-CELL LEAD
9, 19 INTER-LINE LEAD
19a LIGHT-RECEIVING-SURFACE-SIDE OVERLAPPING PORTION
19b BACK-SURFACE-SIDE OVERLAPPING PORTION
10 CELL LINE
10A FIRST CELL LINE
10B SECOND CELL LINE
50 SOLAR BATTERY MODULE

1. A solar battery module in which a plurality of solar battery cells that are respectively formed in flat plates and have light-receiving-surface electrodes on a light-receiving surface side and back-surface electrodes on a back surface side are arranged longitudinally and transversely, and the light-receiving-surface electrodes and the back-surface electrodes of adjacent ones of the solar battery cells are connected sequentially with leads, the module comprising:
a first cell line formed by arraying the solar battery cells in a first direction;
a first inter-cell lead that connects the solar battery cells that form the first cell line in an array direction;
a second cell line formed by arraying the solar battery cells in parallel to the first cell line;
a second inter-cell lead that connects the solar battery cells that form the second cell line in an array direction; and
an inter-line lead that extends in a direction perpendicular to the first direction and electrically connects the first inter-cell lead and the second inter-cell lead, wherein
the inter-line lead overlaps on the back surface side at least either one of the solar battery cell in the first cell line and the solar battery cell in the second cell line.

2. The solar battery module according to claim 1, wherein a light-receiving-surface-side overlapping portion of the inter-line lead, extending on the light-receiving surface of the solar battery cell, is smaller in width than a back-surface-side overlapping portion of the inter-line lead, extending on the back surface side of the solar battery cell.

3. The solar battery module according to claim 1, wherein the first cell line and the second cell line are arranged to be displaced in the first direction in such a manner that a portion of the inter-line lead, extending on the back surface side of the solar battery cell in either one of the cell lines, overlaps the solar battery cell, and the other portion does not overlap the solar battery cell in the other cell line.

4. A method for manufacturing a solar battery module in which a plurality of solar battery cells that are respectively formed in flat plates and have light-receiving-surface electrodes on a light-receiving surface side and back-surface electrodes on a back surface side are arranged longitudinally and transversely, and the light-receiving-surface electrodes and the back-surface electrodes of adjacent ones of the solar battery cells are connected sequentially with leads, the method comprising:
arraying the solar battery cells in a first direction to form a first cell line;
arraying the solar battery cells in parallel to the first cell line to form a second cell line;
connecting the solar battery cells that form the first cell line with a first inter-cell lead in an array direction;
connecting the solar battery cells that form the second cell line with a second inter-cell lead in an array direction; and
connecting the first inter-cell lead and the second inter-cell lead with an inter-line lead that extends in a direction perpendicular to the first direction and overlaps the solar battery cell on the back surface side in at least either one of the solar battery cell in the first cell line and the solar battery cell in the second cell line.
